(19) United States
(12) Patent Application Publication
(10) Pub. No.: US 2005/0018472 A1
(43) Pub. Date: Jan. 27, 2005

(54) Portable data storage device with layered memory architecture

(76) Inventor: Boon Lum Lim, Singapore (SG)

Correspondence Address: CLARK & BRODY, Suite 600, 1750 K Street, NW, Washington, DC, 20006, US

(21) Appl. No.: 10/615,177

(22) Filed: Jul. 9, 2003

(30) Foreign Application Priority Data
Jul. 19, 2002 (GB) 0216770.8

(51) Int. Cl. G11C 11/00

(52) U.S. Cl. 365/154

(57) ABSTRACT

A portable data storage device is capable of storing and easily transporting large amounts of data and in which access to the data can be secured by a polynominal key generated by pseudo random generated parameters. The device can act as a host or a client in respect of access to the data thereby providing protection not only for the data held within the device but also to the computer to which the device is attached. Data is stored in layered memory architecture providing a secure primary and secondary partition structure.

### FIELD OF INVENTION

This invention relates to a portable data storage device which is capable of storing and easily transporting large amounts of data and in which access to the data can be secured by a polynominal key generated by pseudo random generated parameters and wherein the device can act as a host or a client in respect of access to the data thereby providing protection not only for the data held within the device but also to the computer to which the device is attached and wherein data is stored in layered memory architecture providing a secure primary and secondary partition structure.

### SUMMARY OF INVENTION

This invention provides a data storage disk disposed with a communications interface which uses encryption technology and host/client switchable technology to create a novel architecture and communications protocol to ensure data stored in the disk is secured by means of pseudo random generated parameters and at the same time the architecture provides the user with layer protection which employs a self initiated host/client switchable controller which secures access not only to the data but also access to any host computer to which the disk is attached.

Data stored within the disk is secured by means of memory partition architecture and data protection protocol and procedure such that data within the memory storage is layered and encrypted by reference to a pseudo random generated key. As a consequence of such security it would be impossible for any one to access the data without the primary key input.

The data storage disk is disposed with:
1. A communications interface;
2. A microcontroller with built in switchable input;
3. a primary and secondary memory storage means;
4. A data processing unit;
5. Data and decision means;
6. Secure key processing unit;
7. An access control decision unit;
8. An encrypted smart key storage unit.

The communications interface which may be a USB type interface or other communications interface permits users to access the data stored in the memory means of the device. The communications interface enables a user to reversibly access the data in the storage disk.

The microcontroller is disposed with a switchable input interconnected to a data and decision means for primary and secondary layer memory access. The microcontroller and data and decision means are responsible for interfacing between a host computer and the memory storage means and as such provide a gateway for data storage and retrieval and the processing in and from the flash memory means for authorised users.

The primary and secondary storage means are used to store data to permit selective access to users in accordance with the authorisation granted to the user and access to such data is secured by reference to a secure encrypted key.

The switchable input can be initiated by a host computer to which the device is attached wherein the device acts as a client or the input can be initiated by the microcontroller itself wherein the device acts as a host. Key input can be made from the host computer or directly from the device itself. Such key input can then be analysed by the data and decision means for access to primary and secondary layer memory.

The secure key processing unit is reversibly interconnected with an encrypted smart key storage unit and is further connected to the access control decision unit. The access control decision unit is connected to the data processing unit.

The data processing unit is reversibly interconnected to a primary and secondary flash memory means and is accessed by the and interconnected with the communications interface. The data processing unit permits two way access to the layered memory means.

Access to the data which is stored in the device by reference to an encrypted polynominal key which is generated by reference to a user key input in combination with a factory preset code. To access the data held in the memory means an enrolled user is obliged to input his/her key directly to the device or to a host computer to which the device is connected. By permitting such switchable input access control it enables the user of the device to permit authorised third parties to access the data held in the device via an approved computer host device.

The input key is converted to a pseudo random generated key by means of encryption technology. This encrypted user input key is stored in the memory means. To this encryption key the secure key processing unit adds a factory preset code in a polynominal appending process to produce a secure key. Thus the secure polynominal key is based on a user input key and a factory preset code. This secure encrypted polynominal key is stored in the memory means.

Access to the data requires the user to input the appropriate user key input either through the device or through an approved host computer to which the device is attached. Authentication of the input key permits the user to proceed to encryption key generation procedure and primary and secondary memory access.

Enrollment of users requires users to input a key of their own choice either directly to the device or via the host computer to which the device is attached. The user key is encrypted by reference to pseudo random generated parameters and stored in the memory means. This encrypted key is then combined with a factory preset code to form a secure polynominal key. Such key is pointed and is accessible by a key known as an encryption pointer. User access can be selectively restricted either the primary or secondary memory layer or to both layers.

To access data the user will input his/her input key. The data and decision means for access to the primary and/or secondary layer memory authenticates the user input. An encryption pointer is then prepared by to retrieve the encryption key from the secure partition memory. The encryption key is then combined with the factory preset key to generate a secure polynominal key. This polynominal key is then decrypted by the secure key processing unit. The access control decision unit then grants access to the data which is processed by the data processing unit.

By partitioning the memory means it is possible to selectively restrict access that users may have to the data held in storage. This is achieved by means of layered encryption architecture. The highest level of authorisation would permit the user to all the data stored in the different memory partitions while lower level of authorisation would restrict access to data held in one or other partition layer. It is thus possible to enable a user to permit third parties to access some or all of the data held in the device through selective enrollment procedure. Such third party users would be able to access the data through an authorised host computer by inputting their user key.

### BRIEF DESCRIPTION OF THE DRAWINGS

The invention will now be described by reference to the drawings.

FIG. 1 is a block diagram of the system components.

FIG. 2 is a flowchart of the key encryption scheme for access to the primary and secondary memory means.

### DETAILED DESCRIPTION OF THE PREFERRED EMBODIMENTS

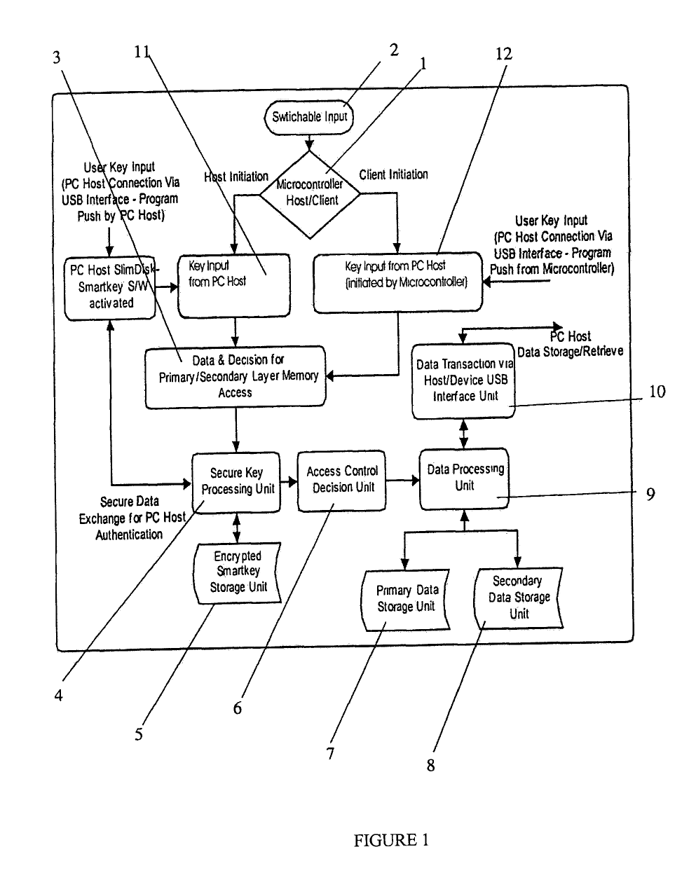

FIG. 1 is a block diagram of the system components. The device is disposed with a communications interface (10) which links the device to a host computer and which is in two way communication with a data processing unit (9). The data processing unit is in communication with an access control decision unit (6) and the primary data storage unit (7) and the secondary data storage unit (8). The access control decision unit is in communication with and receives input from the secure key processing unit (4).

The secure key processing unit is in two way communication with the encrypted smart key storage unit (5) and is also in communication with and receives input from the data and decision means (3) for access to the primary and/or secondary layer memory means and the communications interface.

The data and decision means (3) is in communication with and receives key input from the host computer (11) and/or key input from the device itself (12). The key input is in communication with a micro controller (1) which is in communication with a switchable input (2).

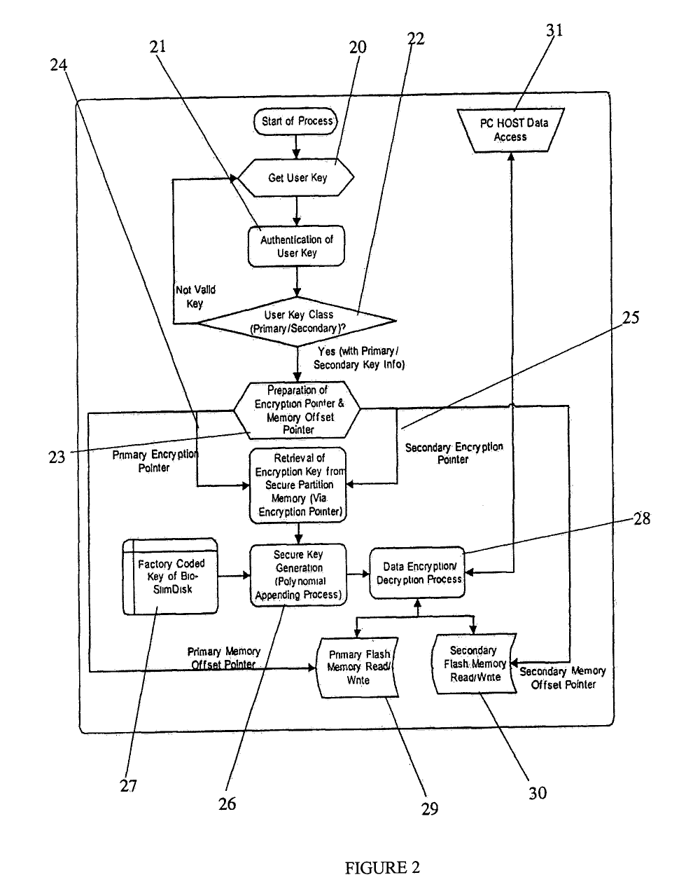

FIG. 2 shows the flow chart of key encryption scheme to access the memory means. At the start of the process the user inputs his/her key input (20). This user key input is then authenticated (21) by the data and decision means (3). The user key input is then evaluated to determine whether the user is entitled to primary and/or secondary level memory access (22). This process is also carried out by the data and decision means (3).

Once the use key input has been authenticated and its access class determined an encryption pointer key is prepared (23). The encryption key in respect of enrolled users is retrieved from the secure memory means (24) for primary level access and (25) for secondary level access by preparing a primary or secondary encryption pointer key.

A secure key is then generated (26) by the secure key processing unit (4) by a polynominal appending process in which the factory encrypted key (27), stored in the encrypted smart key storage unit (5) and the encrypted user key input are combined.

This secure key is then decrypted (28) by the data processing unit (9) to permit the user access to the primary (29) and/or the secondary (30) level memory means. The data can then be accessed via the communications interface (10) linked to a host computer (31).

1. A portable data storage device which can interface with a remote computer such as a desktop PC or a mobile portable notebook computer and which is capable of securing data by reference to a polynomial key generated by pseudo random generated parameters and wherein the device can act as a host or as a client in relation to user access to the data stored therein and wherein the data stored in the device is stored in layered memory architecture and wherein the device is disposed with a communications interface, a microcontroller with a built in switchable input means, a primary and secondary memory storage means, a data processing unit, a data and decision means, a secure key processing unit, an access control decision unit and an encryption smart key storage unit.

2. A device as claimed in claim 1 wherein the communications interface is in two-way communication with the data processing unit.

3. A device as claimed in claim 1 wherein the data processing unit is in communication with the access control decision unit and is in two-way communication with the primary and secondary memory means.

4. A device as claimed in claim 1 wherein the secure key processing unit is reversibly connected with the encrypted smart key storage unit and is further in communication with the access control decision unit.

5. A device as claimed in claim 1 wherein the microcontroller with the built in switchable input is in communication with the data and decision means.

6. A device as claimed in claim 1 wherein the data and decision means is in communication with the secure key processing unit.

7. A memory storage means as claimed in claim 1 wherein the memory means may be volatile or non volatile and wherein the storage means is capable of reversibly receiving and storing data for multi read/write applications.

8. An access control decision unit as claimed in claim 1 wherein the decision unit determines whether a user may have access to the primary and or the secondary layer memory means in accordance to the user key input.

9. A secure key-processing unit as claimed in claim 1 wherein the secure key-processing unit is responsible for the functionality of encrypting and decrypting key input from users.

10. A data processing unit as claimed in claim 1 wherein the data processing unit processes data stored in the primary and secondary memory means prior to access by the user via the communications interface.

11. A microcontroller unit with built in switchable input as claimed in claim 1 wherein the microcontroller provides a gateway whereby a user may interface with the data storage device via a host computer and wherein the switchable input permits the device to act as a host wherein the device protects access to the data stored in the memory means and permits the device to as a client wherein the device can be connected to a host computer and wherein the device can permit authorised users to access the computer to which the device is attached.

12. An encrypted smart key storage unit as claimed in claim 1 wherein a factory preset encrypted key is stored.

13. A data and decision means as claimed in claim 1 wherein the data and decision means authenticates the key input from the user and determines whether the user shall be permitted access to the data stored in the primary and or secondary layer memory means.

14. A process of encryption of users key input wherein key input by the user is converted to a pseudo random generated key in accordance with predefined algorithms and wherein this key is combined with the factory preset key in a polynomial sequence appending process to produce a secure key and wherein the secure key is pointed and is only accessible by an encryption pointer key.

15. A process of encryption as claimed in claim 14 above wherein the secure encrypted polynomial key is stored in the memory means.

16. A process of decryption of key input by a user wherein the key input is evaluated and authenticated by the data and decision means and upon authentication an encryption pointer is prepared by key processing unit to retrieve the secure encryption key from the secure memory means and wherein a secure key is generated by the secure key processing unit in a polynomial sequence appending process wherein the encrypted user key is combined with a factory preset code and wherein this secure key is decrypted by the data processing unit.
